(19) United States
(12) Patent Application Publication
(10) Pub. No.: US 2026/0310579 A1
(43) Pub. Date: Oct. 8, 2026

(54) SYSTEMS AND METHODS FOR CONTROL OF ARBITRARY-PRECISION NUMBERS IN HIGH-LEVEL SYNTHESIS

(71) Applicant: Microsemi SoC Corp., Chandler, AZ (US)

(72) Inventors: Manuel Alejandro Saldana De Fuentes, Toronto (CA); Hassan El-Sheikha, Brampton (CA)

(73) Assignee: Microsemi SoC Corp., Chandler, AZ (US)

(21) Appl. No.: 19/304,364

(22) Filed: Aug. 19, 2025

Related U.S. Application Data
(60) Provisional application No. 63/784,681, filed on Apr. 7, 2025.

(51) Int. Cl. G06F 11/3604

(52) U.S. Cl. CPC G06F 11/3612

(57) ABSTRACT

Techniques are disclosed for runtime analysis of numerical assignments in a high-level synthesis (HLS) environment. Source code and a user-supplied test vector are compiled with a verification library that overloads an operator for a numerical variable that stores a result. The compiling includes inserting code that, for each overloaded operator, redirects the store to a runtime routine, the redirecting being an assignment operation. During execution, the runtime routine evaluates the right-hand side (RHS) variable, determines the bit width range required by the RHS value, and compares the range to the declared bit width of a left-hand side variable. Any mismatch is classified as an overflow quantization error and is logged. After execution, the analysis identifies whether any numerical variable is overprovisioned. The analysis includes a report recommending bit width modifications to correct detected errors, or the system automatically corrects the bit widths in the source code.

### CROSS-REFERENCE TO RELATED APPLICATIONS

The current U.S. non-provisional patent application claims priority benefit of an earlier-filed U.S. provisional patent application titled “SYSTEMS AND METHODS FOR CONTROL OF ARBITRARY PRECISION NUMBERS IN HIGH-LEVEL SYNTHESIS,” Ser. No. 63/784,681, filed Apr. 7, 2025. The U.S. provisional patent application is hereby incorporated by reference, in its entirety, as if fully set forth herein.

### FIELD OF THE DISCLOSURE

Various examples of the present disclosure relate to systems and methods for controlling arbitrary-precision numbers and fixed-point numbers in high-level synthesis (HLS) for field programmable gate arrays (FPGA) based designs.

### BACKGROUND OF THE DISCLOSURE

Some HLS workflows translate C/C++ code into hardware for FPGAs. Developers or designers specify arbitrary-precision integers and fixed-point numbers by declaring explicit bit widths. Existing HLS compilers determine those bit widths only from compile-time constants and static range analysis. When a design instead processes data that appears only at runtime—such as network traffic, sensor streams, or large test bench files—static analysis cannot predict the largest magnitude or finest fractional resolution that will occur. As a result, bit widths are frequently mis-sized. Values may overflow or lose precision if too few bits are declared or silicon area and power may be wasted if overly conservative bit widths are chosen. Current tools leave developers without comprehensive, automated insight into the actual bit width demands of their running designs.

### BRIEF DESCRIPTION

This brief description is provided to introduce a selection of concepts in a simplified form that are further described in the detailed description below. This brief description is not intended to identify key features or essential features of the claimed subject matter, nor is it intended to be used to limit the scope of the claimed subject matter. Other aspects and advantages of the present disclosure will be apparent from the following detailed description of the embodiments and the accompanying figures.

In various aspects, a computer-implemented method for analyzing numerical assignments in a high-level synthesis (HLS) environment is provided. The method includes receiving, by a computing system, source code and a user-supplied test vector. The method also includes compiling the source code with a runtime verification library configured to overload an operator for a numerical variable, the operator including an assignment, arithmetic, or compound-assignment operator that stores a result, and inserting code that, for each overloaded operator, redirects the store to a runtime routine so that the redirected store constitutes an assignment operation. In addition, the method includes executing the compiled source code under the user-supplied test vector. During the operation, for each assignment operation, the runtime routine evaluates a numerical value on a right-hand side (RHS); determines an observed bit width range that represents the RHS numerical value; compares the determined bit width range to a declared bit width of a corresponding left-hand side (LHS) numerical variable; identifies a type of bit width error selected from an overflow or quantization error; and generates an assignment record that logs the determined bit width range and any identified type of bit width error. Furthermore, the method includes identifying, based on the assignment record, whether any numerical variable is overprovisioned, and generating, based on the one or more assignment records, a report including one or more recommended bit width modifications for the source code.

In various aspects, a computing system is provided. The computing system includes one or more processors and a memory. The memory stores computer-executable instructions that, when executed by the one or more processors, cause the one or more processors to perform operations comprising receiving, by the one or more processors, source code and a user-supplied test vector. The one or more processors compile the source code with a runtime verification library configured to overload an operator for a numerical variable, the operator including an assignment, arithmetic, compound-assignment operator that stores a result, and to insert code that, for each overloaded operator, redirects the store to a runtime routine so that the redirected store constitutes an assignment operation. The one or more processors also execute the compiled source code under the user-supplied test vector. For each assignment operation, the runtime routine evaluates a numerical value on a right-hand side (RHS); determines an observed bit width range that represents the RHS numerical value; compares the determined bit width range to a declared bit width of a corresponding left-hand side (LHS) numerical variable; identifies a type of bit width error selected from an overflow or quantization error; and generates an assignment record that logs the determined bit width range and any identified type of bit width error. Moreover, the one or more processors identify, based on the assignment record, whether any numerical variable is overprovisioned, and generate a report including one or more recommended bit width modifications for the source code.

In various aspects, a non-transitory computer-readable medium is provided. The computer-readable medium stores instructions that, when executed by one or more processors, cause the one or more processors to perform operations comprising receiving, by the one or more processors, source code and a user-supplied test vector. The instructions cause the one or more processors to compile the source code with a runtime verification library configured to overload an operator for a numerical variable, the operator including an assignment, arithmetic, or compound-assignment operator that stores a result, and to insert code that, for each overloaded operator, redirects the store to a runtime routine so that the redirected store constitutes an assignment operation. In addition, the instructions cause the one or more processors to execute the compiled source code under the user-supplied test vector. For each assignment operation, the runtime routine evaluates a numerical value on a right-hand side (RHS); determines an observed bit width range that represents the RHS numerical value; compares the determined bit width range to a declared bit width of a corresponding left-hand side (LHS) numerical variable; identifies a type of bit width error selected from an overflow or quantization error; and generates an assignment record that logs the determined bit width range and any identified type of bit width error. Moreover, the instructions cause the one or more processors to identify, based on the assignment record, whether any numerical variable is overprovisioned, and generate a report including one or more recommended bit width modifications for the source code.

A variety of additional aspects will be set forth in the detailed description that follows. These aspects can relate to individual features and to combinations of features. Advantages of these and other aspects will become more apparent to those skilled in the art from the following description of the exemplary embodiments which have been shown and described by way of illustration. As will be realized, the present aspects described herein may be capable of other and different aspects, and their details are capable of modification in various respects. Accordingly, the figures and description are to be regarded as illustrative in nature and not as restrictive.

### BRIEF DESCRIPTION OF THE DRAWINGS

Various examples of the current technology are described in detail below with reference to the attached drawing figures, wherein:

FIG. 1 illustrates an example of a system architecture configured to perform operations of the various examples of the present disclosure;

FIG. 2A depicts a portion of a schematic flow diagram of a compile-time method that scans assignment operations in a high-level synthesis (HLS) design to detect one or more of overflow, quantization, and overprovisioning conditions of one or more of arbitrary-precision numbers and fixed-point numbers;

FIG. 2B is a continuation of the schematic flow diagram of FIG. 2A; and

FIG. 3 is a flow diagram of a process flow for determining an appropriate bit width for each assignment to reduce overflow and quantization errors, and the unnecessary use of FPGA resources.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION OF THE DISCLOSURE

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example, or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples provide methods and systems for detecting and reducing errors including, without limitation, overflows, quantization, and overprovisioning for arbitrary-precision numbers and fixed-point numbers in high-level synthesis (HLS) for FPGA designs.

In digital designs, commands, codes, test vectors, or inputs may be written in languages such as Verilog, VHDL (very high-speed integrated circuit (VHSIC) description language), and HLS (including C++ or other high-level programming languages). The process of determining optimal bit width(s) for arbitrary-precision or fixed-point numbers may present significant challenges. If a bit width allocated to a number is too small, the number may cause overflow, leading to incorrect results or quantization errors. Overflows especially may be considered critical errors of immediate concern. In some examples, if the bit width is too large, the number results in overprovisioning, which wastes FPGA resources (area) and consumes more power than necessary. Overprovisioning is inefficient and may complicate compilation and timing. These issues or errors may be difficult to identify and often require extensive debugging, particularly in designs that contain many arbitrary-precision data types. In some scenarios, conversions from floating point to fixed-point representations may become prone to overflows and quantization errors. Programs or flows with overflowed or quantized numbers may operate without visible errors, even though they may produce incorrect results.

Traditional HLS compilers decide how many bits to allocate by propagating constants and ranges while the source code is compiled. That approach works only when every right-hand side (RHS) value is known in advance (e.g., at compile time). Whenever the RHS depends, for example, on live network traffic, streaming sensor data, or user-supplied test vectors at runtime, traditional compilers either guess large widths, which wastes silicon, or risk overflow. The present disclosure therefore postpones bit range analysis until runtime, when concrete values are available, and bases bit width decisions on the largest and smallest magnitudes that actually pass through the design.

The present disclosure provides methods and systems that help developers or users choose, select, automatically determine, or generate optimal bit widths that reduce overflows, quantization, and overprovisioning errors while avoiding unnecessary resource consumption. For example, the methods and systems may be implemented at runtime based on knowledge of the values assigned to the user's numbers or bit widths and may catch or detect errors or issues early in the FPGA HLS flow to save a user or developer's time while accurately determining appropriate bit widths.

The methods and systems of the present disclosure may be configured to execute user-supplied test vectors and test benches against source code and, for each numerical variable encountered during runtime: determine the bit width range to represent the variable's runtime values; identify any overflow, quantization, or overprovision conditions; and, where appropriate, recommend or automatically apply an updated bit width. Example operations may include overloading the assignment, arithmetic, or compound assignment operators of one or more arbitrary-precision and fixed-point variables (e.g., hls::ap_[u]int and hls::ap_[u]fixpt). During execution of the user-supplied test vectors and test benches, the overloaded operators intercept each runtime assignment or expression, determine the bit range actually used by the right-hand value, compare it to the declared bit width of the left-hand variable, and record the maximum width required for that variable. Based on the comparison, a type of bit width error may be identified. In some examples, the operations may involve generating reports containing one or more types of bit width error and presenting the report on a display unit of a computing system (user system). As used herein, the term “numerical variable” includes any variable stored as binary digits with a declared bit width, including arbitrary-precision integers and fixed-point numbers.

Depending on the error type, one or more actions may be performed, for example computing new bit widths for the variable or modifying the variable according to the calculated bit widths. In various examples, the operations may involve changing the variable test vector to a new test vector by converting or adjusting the test vector values based on the computed bit widths. In some examples, the operations may involve determining bit widths for operations or functions associated with drivers, ports or components of the FPGA design.

During execution the disclosed tool is indifferent to where a value originated. Whether a number comes from a compile-time constant, a disk file, or a network, the tool records the highest bit set and the lowest fractional bit used. By unifying the observations across all sources, the tool recommends a single bit width that anticipates a worst-case scenario.

In various examples, methods and systems of the present disclosure may let a developer specify tolerance margins for both the integer portion and the fractional portion of a numeric type. An overflow alert may be raised only when the most significant bit actually used during code execution exceeds the declared integer bit width by more than the configured integer range margin. Similarly, a quantization alert may be raised only when the least significant fractional bit required during execution is farther to the right of the declared fractional bit width than the configured fractional range margin allows. An overprovisioning notice can be suppressed unless the declared integer bit width exceeds the maximum integer bit width observed by more than the integer range margin or the declared fractional bit width exceeds the minimum fractional bit width observed by more than the fractional range margin. The user-supplied tolerances may be provided through compile-time directives, environment variables, or a configuration file read when the compiled source code is executed.

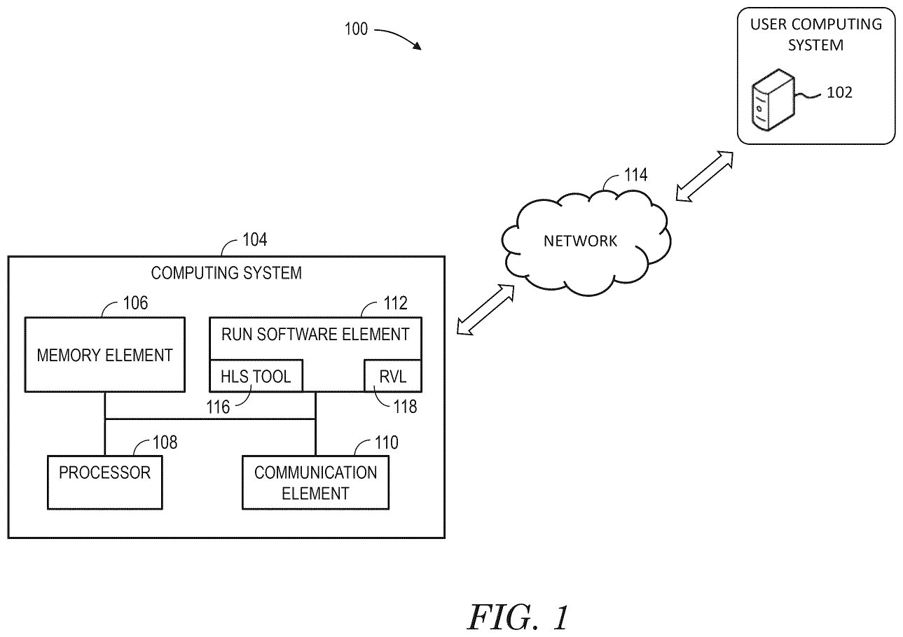

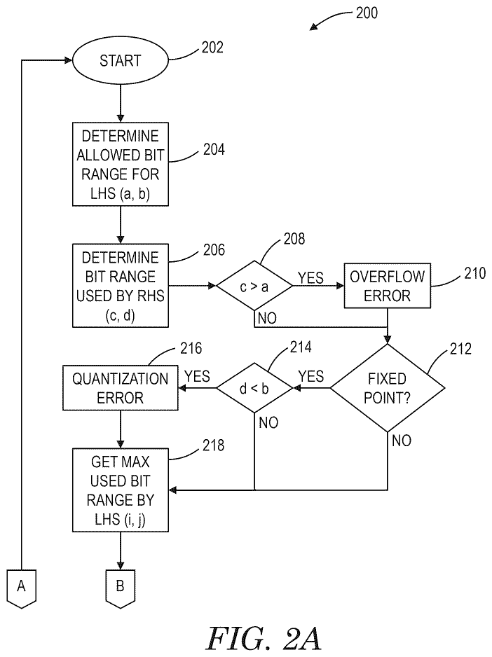

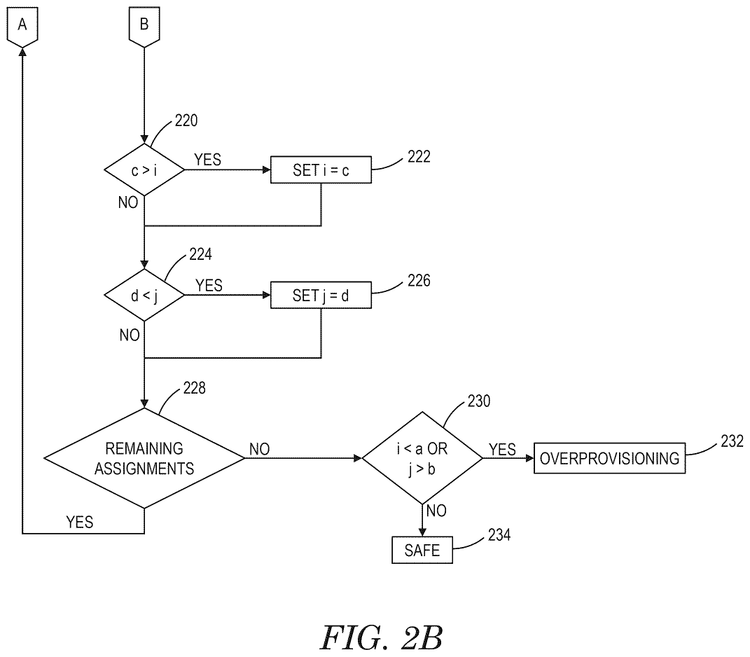

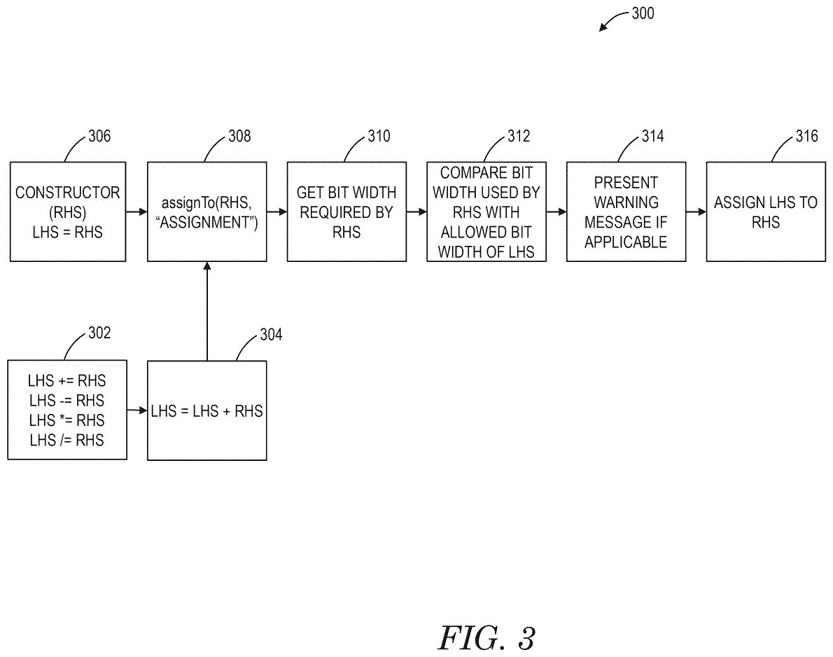

FIG. 1 illustrates an example of a computing environment 100 with various computing systems configured to perform operations as described in the present disclosure. In various aspects, the environment 100 may include computing systems 102 and 104. In this example, computing system 102 may be associated with a user or developer for writing or importing source code and creating test vectors, for example, C or C++ code. Computing system 104 may perform the functions, aspects, and operations of the methods or process flows described herein (e.g., in FIGS. 2 and 3). Alternatively, the user computing system 102 and computing system 104 may be a single system or sub-systems of one another. Each of systems 102 and 104 may be exemplified by workstations, desktop computers, laptops, palmtops, notebook computers, tablets, or similar devices.

In some examples, the user computing system 102 and computing system 104 may be communicating over a network 114, without limitation. The network 114 may include the Internet, cellular communication networks, local area networks, metro area networks, wide area networks, cloud networks, plain old telephone service (POTS) networks, and the like, or combinations thereof. The network 114 may be wired, wireless, or combinations thereof and may include components such as modems, gateways, switches, routers, hubs, access points, repeaters, towers, and the like. The computing system 104 may, for example, connect to communication network 114 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The computing system 104 may include, but not be limited to, a memory element 106, processor(s) 108, a communication element 110, and a run software element 112. The run software element 112 may include a software package that includes an HLS tool 116 and a runtime verification library 118. The HLS tool 116 may operate at compile time to augment (or instrument) source code. The runtime verification library 118 may be invoked by compiled source code to perform assignment checks as described in FIG. 3 below. In various examples, the runtime verification library 118 may be a runtime component of the HLS tool 116.

The memory element 106 may be embodied by devices or components that store data in general, and digital or binary data in particular, and may include example electronic hardware data storage devices or components such as read-only memory (ROM), programmable ROM, erasable programmable ROM, random-access memory (RAM) such as static RAM (SRAM) or dynamic RAM (DRAM), cache memory, hard disks, optical disks, flash memory, thumb drives, universal serial bus (USB) drives, solid state memory, or the like, or combinations thereof. In various examples, the memory element 106 may be embedded in, or packaged in the same package as, the processor 108. The memory element 106 may include, constitute, or embody, a non-transitory “computer-readable medium”. The memory element 106 may store the instructions, code, code statements, code segments, software, firmware, programs, applications, apps, services, daemons, or the like that are executed by the processor 108. The memory element 106 is in electronic communication with the processor 108 and may also store data that is received by the processor 108 or the device in which the processor 108 is implemented. The processor 108 may further store data or intermediate results generated during processing, calculations, and computations as well as data or final results after processing, calculations, and computations. For example, the memory element 106 may store settings, text data, documents from word processing software, spreadsheet software and other software applications, sampled audio sound files, photograph or other image data, movie data, databases, and the like that may be associated with the source codes, operations, functions written in languages C, C++, or any Verilog related language. The memory element 106 may also store applications, software instructions or units for processing or executing functions or operations of the run software element 112. Also, the memory element 106 may store a plurality of operators and a plurality of operands of a plurality of classes and a plurality of threshold or maximum allowed range of bits.

The processor 108 may be coupled to the memory element 106 and other elements of the computing system 104. The processor 108 may comprise one or more processors that include electronic hardware components such as microprocessors (single-core or multi-core), microcontrollers, digital signal processors (DSPs), field-programmable gate arrays (FPGAs), analog or digital application-specific integrated circuits (ASICs), intelligence circuitry, or the like, or combinations thereof. The processor 108 may include or comprise one or more digital processing unit(s). The processor 108 may generally execute, process, or run instructions, code, code segments, code statements, software, firmware, programs, applications, apps, processes, services, daemons, or the like. The processor 108 may also include hardware components such as registers, finite-state machines, sequential and combinational logic, configurable logic blocks, and other electronic circuits that can perform the functions necessary for the operation of various examples of the present technology. In various examples, the processor 108 may include multiple computational components and functional blocks that are packaged separately but function as a single unit. In various examples, the processor 108 may further include multiprocessor architectures, parallel processor architectures, processor clusters, and the like, which provide high performance computing. The processor 108 may be in electronic communication with the other electronic components of the computing system 104 through serial or parallel links that include universal busses, address busses, data busses, control lines, and the like. In addition, the processor 108 may include analog to digital converters (ADCs) to convert analog electronic signals to digital data values in binary form (such as by sampling), or streams of digital data values, or digital to analog converters (DACs) to convert digital data values, or streams of digital data values, to analog electronic signals.

The communication element 110 generally allows the computing system 104 to communicate with other computing systems, devices, external systems, networks 114, computing networks, telecommunication networks, the Internet, and the like. The communication element 110 may include signal and data transmitting and receiving circuits, such as antennas, amplifiers, filters, mixers, oscillators, digital signal processors (DSPs), and the like. The communication element 110 may establish communication wirelessly by utilizing radio frequency (RF) signals and data that comply with communication standards such as cellular 2G, 3G, 4G, Voice over Internet Protocol (VoIP), LTE, Voice over LTE (VoLTE), or 5G, Institute of Electrical and Electronics Engineers (IEEE) 802.11 standard such as WiFi, IEEE 802.16 standard such as WiMAX, Bluetooth™, or combinations thereof. In addition, the communication element 110 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 110 may establish communication through connectors or couplers that receive metal conductor wires or cables which are compatible with networking technologies such as ethernet. In various examples, the communication element 110 may also be coupled with optical fiber cables. The communication element 110 may be in electronic communication with the memory element 106 and the processor(s) 108.

In various examples, the run software element 112 comprises instructions stored on computer-readable media of memory element 106. The run software element 112 includes both the HLS tool 116 and the runtime verification library 118. Together the instructions enable the operations of FIGS. 2 and 3.

Through hardware, software, firmware, or various combinations thereof, the elements 106, 108, 110 and 112 may—alone or in combination with other elements—be configured to perform the operations of embodiments of the present disclosure. The examples described herein in connection with the attached drawing figures are intended to describe aspects of the disclosure in sufficient detail to enable those skilled in the art to practice the disclosure. Other examples can be utilized, and changes can be made without departing from the scope of the present disclosure. The system may include additional, less, or alternate functionality and device(s), including those discussed elsewhere herein. The above detailed description is, therefore, not to be taken in a limiting sense. The scope of the present disclosure is defined only by the appended claims, along with the full scope of equivalents to which such claims are entitled, unless otherwise expressly stated or readily apparent to those skilled in the art from the description.

FIGS. 2A and 2B depict a schematic flow diagram of a compile-time method 200 that scans assignment operations in a high-level synthesis (HLS) design to detect one or more of overflow, quantization, and overprovisioning conditions of one or more of arbitrary-precision numbers and fixed-point numbers. The operations may be performed in the order shown in FIGS. 2A and 2B, or they may be performed in a different order. Further, some operations may be performed concurrently as opposed to sequentially, and some operations may be optional.

The method 200 may be performed by a computing system (e.g., one or more of the user computing system 102 and the computing system 104 of FIG. 1). However, aspects of the method 200 attributed in examples to one of the computing system 102 or 104 may instead be performed by the other, or by other computing devices within the scope of the present disclosure.

One or more computer-readable medium(s) may also be provided. The computer-readable medium(s) may include one or more executable programs stored thereon, such as firmware programs, wherein the program(s) instruct one or more processing elements to perform all or certain of the operations outlined herein. The program(s) stored on the computer-readable medium(s) may instruct the processing element(s) to perform additional, fewer, or alternative actions, including those discussed elsewhere herein.

In the illustrated example, the method 200 may also include solutions for reducing the bit width error(s) based on the type of error(s). For example, the method 200 may use the process flow 300 shown in FIG. 3 to provide solutions for reducing the bit width error(s). In some examples, either or both of the method 200 and the process flow 300 may be implemented or executed at runtime to detect errors early in the HLS flow to save the user time. In some examples, the software may be run, or be executed on or by, the HLS tool 116 in connection with performing the operations of the method 200 and the runtime verification library 118 in connection with the process flow 300. For clarity, the term “HLS tool” includes an overall synthesis environment, while the term “runtime verification library” denotes a subset of the HLS tool that executes inside the compiled source code to monitor bit width usage.

Referring to FIG. 2A, at operation 202, the method 200 includes the computing system 104 importing or otherwise receiving or loading source code including user-supplied test vectors and test benches. In various examples, the HLS tool 116 of the computing system 104 may detect project(s) and write operations from user computing system 102. The source code and the test vectors may be compiled using software GCC (GNU compiler collection) or other C++ compiler.

In various examples, during compilation, the HLS tool 116 may overload one or more (e.g., all) assignment, arithmetic, or compound assignment operators (e.g., “=,” “+=,” “−=,” “*=,” and the like) so that each such operator call is replaced with a runtime routine (illustrated in FIG. 3 as process flow 300). For example, the HLS tool 116 may internally rewrite the statement as a standard assignment and then invoke the runtime routine. Each time the inserted instrumentation reroutes a write through the runtime routine, the redirected write may be referred to herein as an “assignment operation.” In connection with execution of the compiled source code under the user-supplied test vectors and test benches, the runtime routine may perform the programmed assignment and generate an assignment record that identifies the destination variable and the value assigned. For example, the runtime routine may evaluate the right-hand expression, determine the observed bit range, log any overflow or quantization warnings, update a summary table, and write the value to the left-hand variable.

The runtime routine may run only when the processor(s) 108 reaches the assignment statement during execution of the compiled source code. If the assignment statement is skipped because a branch chooses a different path or a loop ends before entering the loop body, the runtime routine does not run, no assignment record is generated, and no analysis overhead is incurred by the HLS tool 116. After all test vectors and test benches have finished executing, the HLS tool 116 may scan the generated assignment records to determine which source code statements were executed. In various examples, the HLS tool 116 may write a record of any unexecuted statements in an optional summary table discussed further herein. A detailed operation of the runtime routine, including overflow, quantization, and runtime record keeping, is described further below.

The HLS tool 116 may, for example after execution of all test vectors and test benches, compute a statement coverage metric by comparing a set of source code line numbers present in assignment records against a complete set of instrumented assignment locations. Any location that generated zero (0) records may be flagged, for example, as “uncovered.” The summary table may include a coverage ratio (executed/total) for the compiled source code and for each individual function. The HLS tool 116 may rank the unexecuted code paths according to how many downstream branches each path controls and suggest that the user add one or more test vectors and test benches to cover highly ranked gaps.

At operation 204, the HLS tool 116 determines a maximum or threshold (a first threshold) allowed bit range(s) for left-hand side (LHS) integer variables (or bit range pairs), for example, (a, b). Also, at operation 206, the HLS tool 116 determines bit range(s) being used by right-hand side (RHS) integer variables (or bit range pairs), for example, (c, d). For example, different classes (such as, hls::ap_[u]int and hls::ap_[u]fixpt classes, without limitation) may be applied to calculate a range of bits used by the test vector in RHS (object). The range of bits currently being used may be different from the maximum allowed range. The calculation of range of bits for RHS may involve stripping away the number of leading zeros and sign bits (and the number of trailing zeros, in the case of fixed-point numbers) to determine the range of bits actually required for representing the number.

In various examples, after operations 204 and 206 have identified the declared bit range (a, b) for the destination variable and the instantaneous bit range (c, d) required by the source value captured in the assignment record, the HLS tool 116 may write the values to the summary table mapped to the destination variable. After writing the initial values, the HLS tool 116 may initialize two per-variable lifetime records: (i) cₘₐₓ, and (ii) dₘᵢₙ. The summary table may retain the greatest upper value “c” and the smallest lower value “d” observed across all assignments. For example, the HLS tool 116 may update cₘₐₓ to be the greater of its current value and “c.” Additionally, the HLS tool 116 may update dₘᵢₙ to be the lesser of its current value and “d.” The updates facilitate consolidating runtime information that can later guide overflow protection or hardware width reduction recommendations, as discussed below. In various examples, the smallest lower value “d” may be recorded only when the destination variable is a fixed-point variable. For integer variables, the smallest lower value “d” may be omitted because fractional bit quantization does not apply. The selective recording supplies the data needed for later width optimization recommendations, as discussed below, without collecting immaterial metrics.

At operation 208, the HLS tool 116 checks whether “c” is greater than “a” (c>a). If the condition is satisfied, an overflow error is flagged at operation 210. At operation 212, the HLS tool 116 queries the declared type of the destination variable. If the variable is a fixed-point object (i.e., hls::ap_[u]fixpt, which has a fractional field), the method 200 proceeds to a quantization error decision path (reference characters 214 and 216). If the variable is an integer object (i.e., hls::ap_[u]int), the quantization branch is skipped, and execution continues to the next analysis stage at operation 218.

If the destination variable is a fixed-point object, the HLS tool 116 evaluates whether the RHS lower index “d” is less than the LHS lower index “b” (d<b) at operation 214. If the condition is satisfied, a quantization error is flagged at operation 216. At operation 228, the HLS tool 116 records the additional fractional bits required so that “b” is less than or equal to “d” (b≤d), for example, in the summary table. Consider a four-bit fixed-point type that reserves three bits for the integer part and one bit for the fractional part. Assigning the numeric value 2.25 requires two fractional bits, so the lowest bit actually used lies one position below the fractional limit declared for the variable. Because the observed bottom bit is lower than b, the HLS tool 116 may identify a quantization loss and may recommend enlarging the corresponding bit range to five bits while keeping the same number of integer bits. In various examples, if a subsequently generated RHS value for the variable has a higher fractional value (e.g., d′>dₘᵢₙ) the stored dₘᵢₙ is left unchanged, thereby ensuring the recorded range remains the tightest range that covers all observed values.

The overloaded operators execute a two-phase numeric integrity routine: (i) an overflow comparison (c>a) for each variable type or object, and (ii) for fixed-point variables or objects, a quantization error comparison (d<b). The operations ensure that integer variables incur no unnecessary fractional bit logic, while fixed-point variables receive both overflow and quantization analysis. The method 200 therefore recommends the left side extension for all variables and the right-side extension solely for fixed-point variables.

Referring again to FIG. 2A, at operation 218, the HLS tool 116 determines a maximum or threshold (second threshold) used bit range (i, j) for the LHS variable. As depicted in FIG. 2B, the operation 218 of determining the maximum or threshold (second threshold) includes, at operation 220, the HLS tool 116 checking a condition of whether “c” is greater than “i” (c>i). If the condition is satisfied, the HLS tool 116 sets the value “i” of the LHS equal to the value “c” of the RHS (set i=c) at operation 222 to avoid or reduce overflow error. Accordingly, the bit width of the LHS may be adjusted such that “a” is greater than or equal to “c” (a>=c) to avoid overflow error.

In various examples, if reducing quantization error for fixed-point variables, the HLS tool 116 may perform operation 224 to check the condition of whether the value of the RHS “d” is less than the value of the LHS “j” (d<j). If the condition is satisfied, the HLS tool 116 sets the value “j” of the LHS equal to value “d” of the RHS (set j=d) at operation 226 to avoid or reduce quantization error. If the condition of operation 224 results in not satisfied, the method 200 moves to operation 228.

At operation 228, the HLS tool 116 may evaluate whether the remaining assignments are applied. If the condition is satisfied, error detection may be iterated (i.e., the method returns to operation 202) until no more errors are found. In various examples, for any modification (i.e., assignment) to an integer (hls::ap_[u]int) or fixed-point (hls::ap_[u]fixpt) object, the number of bits used by the object can be recalculated. Additionally, the maximum bit range used during the object's lifetime may be tracked, as discussed above, via the summary table.

Upon destruction of the object, the HLS tool 116 may check whether the maximum range recorded is smaller than the allowed maximum range, for example, based on the assignment records. If the maximum range recorded is smaller than the allowed maximum range, there is an opportunity to optimize by reducing the allocated bit width for the number. For example, if the condition at operation 228 is not satisfied, at operation 230, the HLS tool 116 may check whether the value of the LHS “i” is less than the value of the LHS “a” or whether the value of the LHS “j” is greater than the value of the LHS “b” (i<a or j>b). If the condition is satisfied, an overprovisioning error may be flagged at operation 232. If the condition is not satisfied, the process may be flagged as safe at operation 234.

In various embodiments, at the end of the analysis at operation 234, the HLS tool 116 may scan the summary table. The summary table may include, for every analyzed software program, a number of executable assignment statements, a number of the executable assignment statements that generated assignment records, a total count of the generated assignment records, a fraction of flow paths exercised, a declared bit range for a respective assignment, a maximum bit range used for the respective assignment, and one or more warning messages associated with each respective assignment. Any function that did not reach full coverage may be highlighted, and a warning may advise the user to add more test vectors and test benches before relying on the width recommendations.

With respect to the one or more warning messages, an overflow condition may be detected when the maximum simulated value of the variable, “cₘₐₓ,” exceeds the maximum value representable by its assigned data type, “a” (cₘₐₓ>a). When an overflow occurs, the system may generate an alert recommending that the total bit width be extended to satisfy the condition where the maximum value of the data type is greater than or equal to the maximum simulated value of the variable (a≥cₘₐₓ).

Similarly, for fixed-point variables, a potential for insufficient quantization precision is identified if the precision required by the variable, “dₘᵢₙ.” is less than the precision provided by its data type, “b” (dₘᵢₙ<b). An alert may be generated that recommends extending the total bit width, and in particular, the fractional length to ensure the precision of the data type is less than or equal to the minimum required precision (b≤dₘᵢₙ).

Conversely, a variable is flagged as overprovisioned if the maximum simulated value of the variable is less than the maximum representable value of its data type (cₘₐₓ<a) and, in the case of fixed-point variables, the minimum required precision is greater than that of the data type (dₘᵢₙ>b). When overprovisioning occurs, the system may generate an alert that prompts the user to reduce the total bit width of the variable to facilitate reducing memory usage and increasing efficiency.

As discussed above, the compile-time method 200 of FIGS. 2A and 2B is executed by the HLS tool 116 and produces an augmented (or instrumented) binary (i.e., compiled source code) that contains a runtime verification library 118. During normal program execution, every assignment that writes to an arbitrary-precision object invokes the routine of FIG. 3 once. Thus, the method 200 governs the design loop (compile→run→analyze), while the process flow 300 provides per-assignment runtime checks that generate the bit width warnings consumed by the outer loop. In various examples, each operation of the method 200 ultimately transmits control to the corresponding operation of FIG. 3 as described in detailed below.

FIG. 3 is a flow diagram of a method or process flow 300 for determining an appropriate bit width for each assignment to reduce overflow and quantization errors and the unnecessary use of FPGA resources. The process flow 300 may be referred to herein as the “runtime routine” described above. The operations may be performed in the order shown in FIG. 3, or they may be performed in a different order. Further, some operations may be performed concurrently as opposed to sequentially, and some operations may be optional.

The process flow 300 may be performed by a computing system (e.g., one or more of the user computing system 102 and the computing system 104 of FIG. 1). However, aspects of the process flow 300 attributed in examples to one of the computing system 102 or 104 may instead be performed by the other, or by other computing devices within the scope of the present disclosure. In the depicted example, the runtime routine may invoke the assignment function (assignTo( )) described herein.

One or more computer-readable medium(s) may also be provided. The computer-readable medium(s) may include one or more executable programs stored thereon, such as firmware programs, wherein the program(s) instruct one or more processing elements to perform all or certain of the operations outlined herein. The program(s) stored on the computer-readable medium(s) may instruct the processing element(s) to perform additional, fewer, or alternative actions, including those discussed elsewhere herein.

At operation 302, the runtime verification library 118 may intercept each assignment operator that writes back to a left-hand side (LHS) arbitrary-precision object (e.g., +=, −=, *=, and /=). The runtime verification library 118 may overload the assignment operators so that, when executed, the runtime verification library 118 may capture a source code location of the assignment, a declared bit width of the LHS (total width “W,” integer width “I_W”), and the current runtime numeric value of the right-hand side (RHS). The captured details may be written in an assignment record that accompanies the value through the remaining operations of the process flow 300.

At operation 304, the runtime verification library 118 may process each assignment by converting the assignment into a standardized (i.e., canonical) representation. For example, the assignment LHS+=RHS may become LHS equals LHS plus RHS (LHS=LHS+RHS). Rewriting each assignment to a standardized form helps ensure that each assignment is processed by a single overloaded assignment function (e.g., assignTo( ), discussed in operation 308).

At operation 306, the runtime verification library 118 may evaluate the RHS expression. The runtime verification library 118 may create a temporary placeholder that may capture the full numeric properties of the RHS—such as bit width, whether the value includes the ability to be negative or not, and any fixed-point precision—by invoking the arbitrary-precision constructor. During the construction process, sign extension may be normalized, fixed-point values may be rounded if required, and the placeholder may be tagged with an initial used range (cᵢₙᵢₜ, dᵢₙᵢₜ). After the placeholder is ready, execution may proceed to the assignment LHS=RHS, which applies the same overflow detection and range validation logic to update the LHS.

At operation 308, the runtime verification library 118 may call the assignment function, i.e., assignTo(RHS, “assignment”), passing the evaluated RHS value and a context string. The assignment function may centralize bit width checking, verifying that each variable value may fit within the width of the target, and may issue any necessary overflow or truncation warnings for each variable type.

At operation 310, the assignment function may determine the bit width currently required or used by the RHS. For example, the assignment function may scan upward to find the most significant non-redundant bit (“c”) and downward to find the least significant non-redundant bit (“d”), thereby establishing the span of significant bits (c−d+1 bits are required).

At operation 312, the runtime verification library 118 may compare bit width used by the RHS (c, d) with an allowed or threshold bit width of the LHS (a, b). As discussed herein, overflow exists when c>a and quantization loss exists when d<b.

At operation 314, the runtime verification library 118 may present one or more warning messages or reports, with warnings and recommendations of optimal bit width. In one or more examples, the runtime verification library 118 may compute the optimal bit widths (via the method 200 described above) and present the results along with the warning messages to the user. The warning messages or reports may include the width adjustment needed. For example, a warning message may state: “Increase total width W from 16 to 24 and integer width I_W from 8 to 13.” In some examples, if an auto-fix flag is enabled for the process flow, the runtime verification library 118 may write the bit width adjustments back into the source code file. The disclosure may include other types of alerts, warnings, reports, and the like to indicate or inform the user or developer about a bit width error and requirement to adjust the bit width(s).

At operation 316, the runtime verification library 118 may assign the LHS to the RHS based on the warnings from operation 314. If the RHS uses fewer bits than allowed by the LHS, the runtime verification library 118 may fill the remaining bits as appropriate to match the declared bit width. If the RHS uses more bits than allowed, the runtime verification library 118 may truncate the value to fit within the declared bit range. After the assignment is completed, the runtime verification library 118 may update the maximum bit range actually used by the LHS during execution in the summary table. The tracking data or record may be used for later analysis that can identify and recommend safe reductions in declared bit width(s).

The present disclosure describes one or more methods to change or update the bit widths of arbitrary-precision numbers and fixed-point numbers in source code. In various examples, one or more of the user computing system 102 and the computing system 104 may present warnings to the user or developer, prompting fixes to the bit widths of the arbitrary-precision numbers and fixed-point numbers in the source code to avoid or reduce errors at runtime. For instance, the method 200 above describes how the HLS tool 116 may detect the locations of operations associated with one or more errors, such as overflow, quantization, and overprovisioning errors. Based on the type of error, the HLS tool 116 (and its runtime verification library 118) may calculate necessary bit widths, including a number of extra bits to the left required to avoid overflows, a number of extra bits to the right required to avoid quantization errors in fixed-point numbers, and a number of bits that may be safely removed from overprovisioned numbers without causing overflow. Accordingly, the HLS tool 116 (and its runtime verification library 118) may provide the calculations in the form of warnings or reports, which the user may use to fix the code, adjust it, and re-run the code until no warnings remain.

Other examples may be automated, according to which the HLS tool 116, via the runtime verification library 118, automates running the software element 112. The HLS tool 116, via the runtime verification library 118, may automatically infer bit widths using test vectors and benches provided by a user, determine initial bit widths, run the compiled source code, adjust the source code according to any warning messages, and repeat the operations until no more warning messages are present.

For example, the HLS tool 116 may participate in an automation loop that iteratively determines final bit width declarations without manual intervention. The loop may perform the following operations: (i) initialize candidate bit widths, optionally defaulting each variable to a single bit width; (ii) compile and execute the source code under a selected test vector suite; (iii) parse the resulting bit width report; (iv) rewrite the source code or an intermediate representation to incorporate each recommended bit width modification; and (v) repeat steps (i)-(iv) until the report contains no further warnings or until a pre-set iteration limit is reached. The loop may run unattended on a developer workstation, such as one or more of the computing systems 102, 104 of FIG. 1, or as part of a continuous integration pipeline, ultimately yielding a hardware design that is sized precisely to the observed data characteristics while preserving functional correctness.

### Feature Combinations

In accordance with various examples, a computer-implemented method may be provided for analyzing numerical assignments in a high-level synthesis (HLS) environment. The method may include receiving, by a computing system, source code along with a user-supplied test vector. The source code may be compiled using a runtime verification library. The compiling includes overloading an operator for a numerical variable. The operator includes one of an assignment, arithmetic, or compound-assignment operator that stores a result. The compiling also includes inserting code into the source code that, for each overloaded operator, redirects the store to a runtime routine. The redirected store is referred to as an assignment operation. Execution of the compiled source code under the test vector may result in, for each assignment operation, the runtime routine, evaluating a right-hand side (RHS) numerical value, and determining a bit width range representing the RHS value. The method may further include the runtime routine comparing the bit width range to a declared bit width of the corresponding left-hand side (LHS) variable, identifying one or more types of bit width error selected from overflow error and quantization error, and generating one or more assignment records that log the determined bit width range and any identified errors. The method includes identifying whether any numerical variable is overprovisioned. A report may be generated that includes one or more recommended bit width modifications for the source code.

In combination with the above examples, the method may further include determining the bit width range by scanning the RHS numerical value and identifying a most significant non-redundant bit and a least significant non-redundant bit. Consistent with the foregoing, the method may also include identifying the overflow error when the most significant non-redundant bit exceeds a declared upper bit position of the LHS variable. Additionally, the method may include identifying the quantization error when the least significant non-redundant bit is less than a declared lower bit position of the LHS variable. The method may also include updating, for each LHS variable, a maximum bit position observed and a minimum bit position observed across each runtime assignment. Identifying whether any numerical variable is overprovisioned includes identifying an overprovisioning condition when the declared upper bit position of the LHS variable exceeds the maximum observed bit position or the declared lower bit position is less than the minimum observed bit position. Further, the method may include obtaining, from a user, an integer range margin, and generating an overflow warning based on the most significant bit position required by the RHS value exceeding the permitted upper bit position of the LHS variable by at least the margin.

In accordance with various examples, a computing system may be provided. The system may include one or more processors and a memory storing computer-executable instructions. When executed by the one or more processors, the instructions may cause the processors to perform operations including receiving source code and a user-supplied test vector and compiling the source code with a runtime verification library. Compiling the source code includes overloading an operator for a numerical variable. The operator includes one of an assignment, arithmetic, or compound-assignment operator that stores a result. Compiling in source code also includes inserting code into the source code that, for each overloaded operator, redirects the store to a runtime routine. The redirected store is referred to as an assignment operation. Executing the compiled source code under the test vector may result in, for each assignment operation, the runtime routine evaluating a right-hand side (RHS) numerical value and determining a bit width range representing the RHS value. The runtime routine may further compare the bit width range to a declared bit width of the corresponding left-hand side (LHS) variable, identify one or more types of bit width error selected from overflow error and quantization error, and generate one or more assignment records that log the determined bit width range and any identified errors. The instructions may also cause the processors to identify whether any numerical variable is overprovisioned. A report may be generated that includes one or more recommended bit width modifications for the source code.

Consistent with the preceding examples, computer-executable instructions may also cause processors to scan the RHS value and identify the most and least significant non-redundant bits. The processors may further identify the overflow error when the most significant non-redundant bit exceeds the declared upper bit position of the LHS variable or the quantization error when the least significant non-redundant bit is less than the declared lower bit position. The instructions may also update, for each LHS variable, the maximum and minimum bit positions observed during execution. Identifying whether any numerical variable is overprovisioned includes identifying an overprovisioning condition when the declared bit positions exceed the maximum or minimum observed during test execution. Additionally, the instructions may obtain a user-defined integer range margin and generate an overflow warning only when the required bit position exceeds the declared bit width by at least the margin.

According to further examples, a non-transitory computer-readable medium may store instructions that, when executed by one or more processors, cause the processors to carry out operations including receiving source code and a user-supplied test vector and compiling the code using a runtime verification library. Compiling the source code includes overloading an operator for a numerical variable. The operator includes one of an assignment, arithmetic, or compound-assignment operator that stores a result. Compiling in source code also includes inserting code into the source code that, for each overloaded operator, redirects the store to a runtime routine. The redirected store is referred to as an assignment operation. The instructions may cause the processors to execute the compiled source code under the test vector. The runtime routine evaluates RHS numerical values; determines corresponding bit width ranges; compares the ranges to LHS declarations; identifies types of bit width errors including overflow and quantization error; and logs assignment records. The processors also carry out operations including identifying whether any numerical variable is overprovisioned and generating a report recommending bit width modifications.

Consistent with previously described examples, stored instructions may further cause processors to scan the RHS value and identify the most and least significant non-redundant bits. The overflow and quantization errors may be identified when the observed bits fall outside the declared range. The instructions may also track the maximum and minimum bit positions observed for each LHS variable and detect overprovisioning conditions accordingly. Additionally, the stored instructions may direct the processors to obtain a user-defined integer range margin and issue an overflow warning only when the required bit width exceeds the declared range by at least the specified margin.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure. For example, although described herein with regard or in relation to one or more particular kinds of electronic devices (e.g., field effect transistors), the technology may be more broadly applicable to one or more other kinds of electronic devices as well.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated or except as will be readily apparent to those skilled in the art from the description. For example, a feature, structure, act, etc. described in one embodiment may also be included in other embodiments but is not necessarily included. Thus, the current technology can include a variety of combinations or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated or readily apparent to those skilled in the art from the description.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A computer-implemented method for analyzing numerical assignments in a high-level synthesis (HLS) environment, the method comprising:
receiving, by a computing system, source code and a user-supplied test vector;
compiling the source code with a runtime verification library, including:
overloading an operator for a numerical variable, the operator including an assignment, arithmetic, or compound-assignment operator that stores a result;
inserting code into the source code that, for each overloaded operator, redirects the store to a runtime routine, the redirected store being an assignment operation;
executing the compiled source code under the user-supplied test vector, wherein, for each assignment operation, the runtime routine:
evaluates a right-hand side (RHS) numerical value;
determines an observed bit width range sufficient to represent the RHS numerical value;
compares the observed bit width range to a declared bit width of a corresponding left-hand side (LHS) numerical variable;
identifies a bit width error selected from overflow error or quantization error; and
generates an assignment record that logs the observed range and the identified bit width error;
identifying, based on the assignment record, whether any numerical variable is overprovisioned; and
generating a report including one or more recommended bit width modifications for the source code.

2. The method of claim 1, wherein determining the observed bit width range comprises:
scanning the RHS numerical value; and
identifying a most significant non-redundant bit and a least significant non-redundant bit.

3. The method of claim 2, further comprising identifying the overflow error based on the most significant non-redundant bit exceeding a declared upper bit position of the LHS numerical variable.

4. The method of claim 2, further comprising identifying the quantization error based on the least significant non-redundant bit being lower than a declared lower bit position of the LHS numerical variable.

5. The method of claim 1, further comprising updating, for each LHS numerical variable, a maximum bit position observed and a minimum bit position observed across each assignment operation executed during runtime.

6. The method of claim 5, wherein identifying whether any numerical variable is overprovisioned comprises identifying an overprovisioning condition based on a declared upper bit position of the LHS numerical variable exceeding the maximum bit position observed or a declared lower bit position of the LHS numerical variable being lower than the minimum bit position observed.

7. The method of claim 1, further comprising:
obtaining, from a user, an integer range margin; and
generating an overflow warning based on a most significant bit position required by the RHS numerical value exceeding a most significant bit position permitted by the declared bit width of the LHS variable by at least the integer range margin.

8. A computing system comprising:
one or more processors; and
a memory storing computer-executable instructions that, when executed by the one or more processors, cause the one or more processors to perform operations comprising:
receiving, by the one or more processors, source code and a user-supplied test vector;
compiling the source code with a runtime verification library, including:
overloading an operator for a numerical variable, the operator including an assignment, arithmetic, or compound-assignment operator that stores a result;
inserting code into the source code that, for each overloaded operator, redirects the store to a runtime routine, the redirected store being an assignment operation;
executing the compiled source code under the user-supplied test vector, wherein, for each assignment operation, the runtime routine:
evaluates a right-hand side (RHS) numerical value;
determines an observed bit width range sufficient to represent the RHS numerical value;
compares the observed bit width range to a declared bit width of a corresponding left-hand side (LHS) numerical variable;
identifies a bit width error selected from overflow error or quantization error; and
generates an assignment record that logs the observed range and the identified bit width error;
identifying, based on the assignment record, whether any numerical variable is overprovisioned; and
generating a report including one or more recommended bit width modifications for the source code.

9. The computing system of claim 8, wherein determining the observed bit width range comprises:
scanning the RHS numerical value; and
identifying a most significant non-redundant bit and a least significant non-redundant bit.

10. The computing system of claim 9, wherein the computer-executable instructions further cause the one or more processors to identify the overflow error based on the most significant non-redundant bit exceeding a declared upper bit position of the LHS numerical variable.

11. The computing system of claim 9, wherein the computer-executable instructions further cause the one or more processors to identify the quantization error based on the least significant non-redundant bit being lower than a declared lower bit position of the LHS numerical variable.

12. The computing system of claim 8, wherein the computer-executable instructions further cause the one or more processors to update, for each LHS numerical variable, a maximum bit position observed and a minimum bit position observed across each assignment operation executed during runtime.

13. The computing system of claim 12, wherein identifying whether any numerical variable is overprovisioned comprises identifying an overprovisioning condition based on a declared upper bit position of the LHS numerical variable exceeding the maximum bit position observed or a declared lower bit position of the LHS numerical variable being lower than the minimum bit position observed.

14. The computing system of claim 8, wherein the computer-executable instructions further cause the one or more processors to:
obtain, from a user, an integer range margin; and
generate an overflow warning based on a most significant bit position required by the RHS numerical value exceeding a most significant bit position permitted by the declared bit width of the LHS numerical variable by at least the integer range margin.

15. A non-transitory computer-readable medium storing instructions that, when executed by one or more processors, cause the one or more processors to perform operations comprising:
receiving, by the by one or more processors, source code and a user-supplied test vector;
compiling the source code with a runtime verification library, including:
overloading an operator for a numerical variable, the operator including an assignment, arithmetic, or compound-assignment operator that stores a result;
inserting code into the source code that, for each overloaded operator, redirects the store to a runtime routine, the redirected store being an assignment operation;
executing the compiled source code under the user-supplied test vector, wherein, for each assignment operation, the runtime routine:
evaluates a right-hand side (RHS) numerical value;
determines an observed bit width range sufficient to represent the RHS numerical value;
compares the observed bit width range to a declared bit width of a corresponding left-hand side (LHS) numerical variable;
identifies a bit width error selected from overflow error or quantization error; and
generates an assignment record that logs the observed range and the identified bit width error;
identifying, based on the assignment record, whether any numerical variable is overprovisioned; and
generating a report including one or more recommended bit width modifications for the source code.

16. The non-transitory computer-readable medium of claim 15, wherein determining the bit width range comprises:
scanning the RHS numerical value; and
identifying a most significant non-redundant bit and a least significant non-redundant bit.

17. The non-transitory computer-readable medium of claim 16, wherein the instructions further cause the one or more processors to identify the overflow error based on the most significant non-redundant bit exceeding a declared upper bit position of the LHS variable.

18. The non-transitory computer-readable medium of claim 16, wherein the instructions further cause the one or more processors to identify the quantization error based on the least significant non-redundant bit being lower than a declared lower bit position of the LHS variable.

19. The non-transitory computer-readable medium of claim 15,
wherein the instructions further cause the one or more processors to update, for each LHS variable, a maximum bit position observed and a minimum bit position observed across each assignment operation executed during runtime,
wherein identifying whether any numerical variable is overprovisioned comprises identifying an overprovisioning condition based on a declared upper bit position of the LHS numerical variable exceeding the maximum bit position observed or a declared lower bit position of the LHS numerical variable being lower than the minimum bit position observed.

20. The non-transitory computer-readable medium of claim 15, wherein the instructions further cause the one or more processors to:
obtain, from a user, an integer range margin; and
generate an overflow warning based on a most significant bit position required by the RHS numerical value exceeding a most significant bit position permitted by the declared bit width of the LHS variable by at least the integer range margin.
